(19) United States
(12) Patent Application Publication
(10) Pub. No.: US 2005/0289421 A1
(43) Pub. Date: Dec. 29, 2005

(54) Semiconductor chip

(76) Inventors: Hermann Obermeir, Munchen (DE); Harry Siebert, Puchheim (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/152,930

(22) Filed: Jun. 15, 2005

(30) Foreign Application Priority Data
Jun. 15, 2004 (DE) DE102004 028632.9

(51) Int. Cl. G01R 31/28

(52) U.S. Cl. 714/726

(57) ABSTRACT

A semiconductor chip has a multiplicity of flipflops which can be connected up to form one or more shift registers for the purpose of testing the semiconductor chip, and having a JTAG test access port based on IEEE 1149.1 which can be used to put the semiconductor chip into a test mode in which the flipflops are connected up to form one or more shift registers. The semiconductor chip described is distinguished in that it is designed such that the one or more shift registers can have information written to and read from it/them via the JTAG test access port.

### CROSS-REFERENCE TO RELATED APPLICATION

This application claims priority from German Patent Application No. 10 2004 028 632.9, which was filed on Jun. 15, 2004, and is incorporated herein by reference in its entirety.

### TECHNICAL FIELD

The present invention relates to a semiconductor chip having a multiplicity of flipflops which can be connected up to form one or more shift registers for the purpose of testing the semiconductor chip, and having a Joint Test Action Group (JTAG) test access port based on the Institute of Electrical and Electronics (IEEE) standard IEEE 1149.1 which can be used to put the semiconductor chip into a test mode in which the flipflops are connected up to form one or more shift registers.

### BACKGROUND

Such a semiconductor chip is a semiconductor chip which can be tested using the “full scan test” method.

The design of such a semiconductor chip is illustrated in FIG. 5. The semiconductor chip shown in FIG. 5 is a program-controlled unit, such as a microcontroller, a microprocessor or a signal processor. However, it could also be any other semiconductor chip which can be tested using the full scan test method. For the sake of completeness, it will be pointed out before continuing that only those components of the semiconductor chip which are of particular interest at present are shown and described.

The semiconductor chip shown in FIG. 5 contains a logic unit 401, a first multiplexer 471, a second multiplexer 472, a third multiplexer 473, a JTAG test access port 420 (subsequently called TAP) and a multiplicity of input and/or output connections, from which FIG. 5 shows only the connections TCK, TDI, TMS, TDO and 481 to 485, however.

The semiconductor chip may also contain any other components, for example one or more central processing units (CPUs), one or more memories etc.

The logic unit 401 contains a multiplicity of logic gates and storage elements. By way of example, the logic gates comprise AND gates, OR gates, XOR gates and/or any other logic gates. The storage elements are formed by flipflops in the example under consideration, these being able to be connected in series, for the purpose of testing the semiconductor chip, such that they then behave like a shift register. The specific way in which this happens is known and requires no further explanation. FIG. 5 shows the state of the semiconductor chip in which the flipflops are connected up to form two shift registers, namely a first shift register 402 and a second shift register 403, and the rest of the logic (essentially the combinational logic) is shown as the logic unit 401. In the present case, two shift registers are described by way of example; in reality, there may be significantly more, depending on the scope of the chip.

The shift registers 402 and 403 can have information written to and read from them from outside of the semiconductor chip, to be more precise by an external test apparatus. For this reason, the input connection of the first flipflop in the first shift register 402 is connected to the input connection 481 of the semiconductor chip, the output connection of the last flipflop in the first shift register 402 is connected to the output connection 482 of the semiconductor chip via the first multiplexer 471, the input connection of the first flipflop in the second shift register 403 is connected to the input connection 483 of the semiconductor chip, and the output connection of the last flipflop in the second shift register 403 is connected to an output connection 484 of the semiconductor chip via the second multiplexer 472. It is thus possible to use the input connections 481 and 483 to write data to the shift registers 402 and 403, and the output connections 482 and 484 can be used to read data from the shift registers 402 and 403.

In the example under consideration, the input connections 481 and 483 and the output connections 482 and 484 are multifunction connections which, in normal operation of the semiconductor chip, i.e. in phases in which the flipflops are not connected up to form the shift registers 402 and 403, can be used as input connections for inputting data into the logic unit 401 and as output connections for outputting data from the logic unit 401. In this case, the multiplexers 471 and 472 decide whether the output connections 482 and 484 are used to output data coming from the shift registers 402 and 403 or data coming from the logic unit 401 from the semiconductor chip; the multiplexers 471 and 472 are supplied not only with the output signals from the shift registers 402 and 403 but also with a respective output signal from the logic unit 401. The multiplexers 471 and 472 are controlled by a signal scan_en. This signal governs whether the data shifted out of the shift registers 402 and 403 or the data coming from the logic unit 401 are output from the semiconductor chip via the output connections 482 and 484. When the control signal scan_en is active, the data coming from the shift registers 402 and 403 are output from the output connections 482 and 484, and when the control signal scan_en is inactive, the output connections 482 and 484 output the data coming from the logic unit 401 from the semiconductor chip. The control signal scan_en is produced by the TAP 420.

The TAP 420 is a JTAG test access port based on IEEE 1149.1. The JTAG test access port based on IEEE 1149.1 was originally developed and standardized for the “boundary scan test”, but is now also used for other purposes. In the example under consideration, it is used to control the testing of the semiconductor chip using the full scan test method.

The TAP 420 is connected to the input connections TCK, TDI and TMS and to the output connection TDO of the semiconductor chip, and produces signals scan_clock, scan_en and scan_mode. The connections of the semiconductor chip, which have the TAP 420 connected to them, have the labels which are also used in the aforementioned standard IEEE 1149.1.

The signal scan_mode is used to control the multiplexers 471 to 473.

As has already been explained above, the multiplexers 471 and 472 are used to select the signals which are to be output via the output connections 482 and 484 of the semiconductor chip.

The multiplexer 473 is used to select the clock signal used by the semiconductor chip. The multiplexer 473 has two input connections, with a first clock signal sys_clock supplied to the semiconductor chip via the input connection 485 being applied to the first input connection, and with the signal scan_clock, which is output from the TAP 420 and is used as the second clock signal, being applied to the second input connection. In this case, the first clock signal is the clock signal which can be used to clock the semiconductor chip during normal operation, and the second clock signal is the clock signal which can be used to clock the semiconductor chip during testing of the semiconductor chip using the full scan test method. The clock signal which is output from the multiplexer 473 is the clock signal which the clock-controlled components of the semiconductor chip use for operation. When the signal scan_mode is active, the multiplexer 473 switches through the signal scan_clock, and when the signal scan_mode is inactive, the multiplexer 473 switches through the signal sys_clock.

The signal scan_mode determines whether the semiconductor chip is in a normal mode or is in a full scan test mode, the normal mode being that mode in which the semiconductor chip is in normal operation and operates as intended, and the full scan test mode being that mode in which the semiconductor chip can be tested using the full scan test method. The signal scan_en additionally determines how the semiconductor chip behaves in the full scan test mode. The TAP 420 is designed and controlled such that the signal scan_en can be active only when the semiconductor chip has been put into the full scan test mode by the signal scan_mode.

In normal mode (scan_mode inactive, scan_en inactive), the multiplexers 471 to 473 are controlled such that the semiconductor chip is clocked using the clock signal obtained by the input connection 485, and the signals which are output from the logic unit 401 are output from the output connections 482 and 484.

In full scan test mode (scan_mode active, scan_en active or inactive), the multiplexers 471 to 473 are controlled such that the semiconductor chip is clocked using the clock signal scan_clock which is output by the TAP 420, and either the signals which are output from the shift registers 402 and 403 (scan_en inactive) or the signals which are output from the logic unit 401 (scan_en inactive) are output from the output connections 482 and 484. In addition, the signal scan_en also determines whether the flipflops in the logic unit 401 are connected up to form the shift registers 402 and 403 (scan_en active) or whether they are not (scan_en inactive). If the semiconductor chip has been put into the full scan test mode by an active signal scan_mode, and the signal scan_en is also active, then the flipflops are connected up to form the shift registers 402 and 403, and the shift registers 402 and 403 can have information written to and read from them from outside of the semiconductor chip via the input and output connections 481 to 484. This mode is subsequently called full scan test/shift mode. If the semiconductor chip has been put into the full scan test mode by an active signal scan_mode, and the signal scan_en is inactive, then the flipflops are not connected up to form the shift registers 402 and 403 and operate as they do in the normal mode of the semiconductor chip; the semiconductor chip operates only with a different clock signal than in the normal mode, with the clock signals also being able to be identical in the case of simple chips. This mode is subsequently called full scan test/capture mode.

The design of the TAP 420 is illustrated in FIG. 6. The TAP 420 contains a state machine 421, an instruction register 422, an AND gate 423 and a multiplexer 424.

The control bits described below are stored in the instruction register 422 in the example under consideration. However, it is likewise possible for one of the “design specific registers” defined in the standard IEEE 1149.1 to be provided for this function instead.

The state machine 421 is connected to the input connections TMS and TCK of the semiconductor chip and is supplied with control bits serially by the input connection TMS and with a clock signal via the input connection TCK. The state machine 421 can assume a total of 16 different states which, in IEEE 1149.1 and also in the description below, are labeled test_logic_reset, run_test/idle, select_dr_scan, capture_dr, shift_dr, exit1_dr, pause_dr, exit2_dr, update_dr, select_ir_scan, capture_ir, shift_ir, exit1_ir, pause_ir, exit2_ir and update_ir. The state in which the state machine 421 is currently is dependent on the control bit sequence supplied to the state machine 421 via the input connection TMS; IEEE 1149.1 stipulates under what circumstances the state machine assumes what state. By way of example,
if the state machine is in the state test_logic_reset, it is held in the state test_logic_reset by a control bit with the value 1 which is supplied to it via the input connection TMS, and is put into the state run_test/idle by a control bit with the value 0 which is supplied to it via the input connection TMS,
if the state machine is in the state run_test/idle, it is held in the state run_test/idle by a control bit with the value 0 which is supplied to it via the input connection TMS, and is put into the state select_dr_scan by a control bit with the value 1 which is supplied to it via the input connection TMS, and
if the state machine is in the state select_dr_scan, it is put into the state capture_dr by a control bit with the value 0 which is supplied to it via the input connection TMS, and is put into the state select_ir_scan by a control bit with the value 1 which is supplied to it via the input connection TMS.

The complete state diagram is illustrated in FIG. 7. For further details, reference is made to the standard IEEE 1149.1.

In the example under consideration, the state machine 421 outputs signals update_ir, shift_ir and *_ir,
where the signal update_ir is active when the state machine is in the state update_ir,
where the signal shift_ir is active when the state machine is in the state shift_ir, and
where the signal *_ir is active when the state machine is in one of the states whose label ends in _ir.

The instruction register 422 is a shift register which comprises a plurality of registers which are respectively designed to store 1 bit. It is connected to the input connections TDI and TCK of the semiconductor chip and is supplied with instruction bits serially by the input connection TDI and with a clock signal via the input connection TCK. The registers in the instruction register 422 can also have information written to and read from them in parallel and without a shift operation.

The instruction register 422 is controlled by the signals update_ir and shift_ir which are output by the state machine 421. The signal update_ir prompts the parallel transfer of data applied to the individual registers in the instruction register 422 into the instruction register, and the signal shift_ir prompts bit-by-bit serial data transfer with a simultaneous shift operation.

Of the bits stored in the instruction register 422, the value of an n-th bit is used as the aforementioned signal scan_mode and is output from the TAP 420, where n may be of arbitrary magnitude. This n-th bit is additionally supplied to the AND gate 423. In addition, the AND gate 423 is supplied with the instruction bit which is currently supplied via the input connection TDI. The AND gate 423 ANDs the signals which are supplied to it. The result of this ANDing is used as the aforementioned signal scan_en and is output from the TAP 420.

The output of the instruction register 422 is connected to one of the input connections of the multiplexer 424. The other input connection of the multiplexer is connected to further registers (not shown) in the TAP 420. The output connection of the multiplexer 424 is connected to the output connection TDO of the semiconductor chip. The multiplexer 424 is controlled by the signal *_ir, so that whenever the state machine is in a state whose label ends in _ir the last bit of the instruction register is output from the output connection TDO. This makes it possible to check whether the TAP 420 is operating correctly. For the sake of completeness, it should be pointed out that the multiplexer 424 may also have more than two input connections, these further input connections being connected to further registers in the TAP (which are not shown in FIG. 6).

In addition, the clock signal supplied to the TAP 420 via the input connection TCK of the semiconductor chip is used as the clock signal scan_clock and is output from the TAP 420. The clock signal supplied to the TAP 420 via the input connection TCK of the semiconductor chip is also used as a clock signal for the clock-controlled components of the TAP 420.

The semiconductor chip as shown in FIG. 5 is now tested using the full scan test method as follows: first, appropriate bit sequences are input via the input connections TDI and TMS in order to put the TAP 420 into a state in which the signals scan_mode and scan_en which are output by the TAP 420 have values which put the semiconductor chip into the full scan test/shift mode. Next, the shift registers 402 and 403 have data representing a test pattern written to them serially bit by bit via the input connections 481 and 483. When this has happened, the semiconductor chip is briefly, for example for one or two clock cycles of the clock signal scan_clock, put into the full scan test/capture mode via the input connections TDI and TMS. In this mode, the shift registers 402 and 403 are cleared, and the logic unit 401, including the flipflops, operates as in the normal mode. Only the clock signal (scan_clock) is different than in the normal mode (sys_clock). In the full scan test/capture mode, the data stored by the flipflops may change. Whether and, if appropriate, how they change is dependent, inter alia, on the data which were loaded into the shift registers 402 and 403 beforehand and on the design and operation of the logic unit 401. Next, the semiconductor chip is put back into the full scan test/shift mode via the input connections TDI and TMS. In this state, the data stored in the shift registers 402 and 403 are read via the output connections 482 and 484. At the same time or thereafter, it is already possible to write data representing another test pattern to the shift registers 402 and 403. The data which are read from the shift registers 402 and 403 are then compared with the prescribed nominal data. The nominal data are those data which ought to be stored in the shift registers 402 and 403 if the semiconductor chip is operating correctly. From the result of the comparison between the data which are read from the shift registers 402 and 403 and the nominal data, it is thus possible to ascertain whether the semiconductor chip is operating correctly. If the data compared with one another match, it may be assumed that the semiconductor chip has operated correctly. If the data do not match, the semiconductor chip has not operated correctly.

The test described above can be repeated as often as desired using other test patterns.

Now and then, such a test may last a very long time. Particularly if the logic unit 401 contains a very large number of flipflops and hence the shift registers 402 and 403 formed from the flipflops are very long, it takes a very long time primarily to write the test patterns to the shift registers and to read the shift registers.

This problem can be avoided if the flipflops in the logic unit 401 are connected up not to form just one or two shift registers but rather to form a larger number of shift registers. The plurality of shift registers then have fewer flipflops and can accordingly have information written to and read from them more quickly.

In this case, however, there need to be a correspondingly larger number of input and output connections for writing and reading information to and from the shift registers and a correspondingly larger number of connections between the semiconductor chip and the test apparatus testing the semiconductor chip. This results in the testing of the semiconductor chip using the full scan test method being more complex than is the case when one or two shift registers are formed. To keep this drawback on a small scale, the number of shift registers formed in the full scan test/shift mode should be kept as small as possible. Ideally, only a single shift register is formed, but this in turn results in the aforementioned time problems.

A further drawback of the semiconductor chip shown in FIGS. 5 and 6 is that it is difficult and sometimes even impossible even to test such semiconductor chips as are already mounted on a printed circuit board using the full scan test method. The reasons for this are twofold. First, when a semiconductor chip is mounted on a printed circuit board it is frequently not possible to gain free access to all input and/or output connections of the semiconductor chip. This is the case by way of example, but not exclusively, for semiconductor chips which are accommodated in ball grid array packages or mounted using flip chip technology. Secondly, one problem is that the input and output connections provided for writing and reading information to and from the shift registers are multifunction connections which can also be used for purposes other than writing and reading information to and from the shift registers, which means that collisions may arise when writing and reading information to and from the shift registers in a semiconductor chip which is already integrated in an existing system.

### SUMMARY

The present invention is therefore based on the object of developing the semiconductor chip, for example, as know in the prior art, such that it can be comprehensively tested quickly and easily under all circumstances, particularly even when it is already fitted in a system.

The invention can achieve this object by a semiconductor chip comprising a multiplicity of flipflops which can be connected up to form one or more shift registers for the purpose of testing the semiconductor chip, and having a Joint Test Action Group (JTAG) test access port based on IEEE 1149.1 which can be used to put the semiconductor chip into a test mode in which the flipflops are connected up to form one or more shift registers, wherein the semiconductor chip is designed such that the one or more shift registers can have information written to and read from it/them via the JTAG test access port.

The at least one shift register can also have information written to and read from it via input and/or output connections of the semiconductor chip which are not connected to the JTAG test access port. The JTAG test access port may produce a first signal, whose level governs whether the at least one shift register can have information written to and read from it via the JTAG test access port or via input and/or output connections of the semiconductor chip which are not connected to the JTAG test access port. The first signal used can be a particular bit of the data stored in an instruction register in the JTAG test access port or is a particular bit of the data stored in one of the other design specific registers defined in IEEE 1149.1. The JTAG test access port may produce a second signal, whose level governs whether or not the semiconductor chip is in the test mode, and the second signal is the result of logically combining bits stored in an instruction register in the JTAG test access port or bits stored in one of the other design specific registers defined in IEEE 1149.1. The JTAG test access port may produce a third signal, whose level governs whether or not the flipflops of the semiconductor chip are connected up to form the at least one shift register, and the third signal is dependent on the state of a state machine in the JTAG test access port. The flipflops of the semiconductor chip can be connected up in the test mode at least to form a first shift register and to form a second shift register, wherein optionally only the first shift register or only the second shift register or both shift registers can have information written to and read from it/them. The content of a design specific register in the JTAG test access port, which register is defined in IEEE 1149.1 and can have information written to it via an input connection TDI of the JTAG test access port, may govern whether only the first shift register or only the second shift register or both shift registers can have information written to and read from it/them. The data to be written to the at least one shift register can be input into the semiconductor chip via an input connection TDI of the JTAG test access port. The data to be written to the at least one shift register can be written to a design specific register which is defined in IEEE 1149.1 and can have information written to it via the input connection TDI of the JTAG test access port, and can be forwarded from there to the at least one shift register. The data to be written to the at least one shift register can be written to the design specific register serially bit by bit and can be forwarded therefrom to the at least one shift register in parallel. The at least one shift register may have information written to it in a plurality of successive steps, with one bit per shift register being written to the design specific register and being forwarded from there to the at least one shift register in each step. The data to be read from the at least one shift register can be output from the semiconductor chip via an output connection TDO of the JTAG test access port. The data to be read from the at least one shift register can be transferred to a design specific register in the JTAG test access port, which register is defined in IEEE 1149.1, and from there it can be output from the semiconductor chip via the output connection TDO of the JTAG test access port. The data to be read from the at least one shift register can be transferred in parallel to the design specific register and from there it can be output serially bit by bit from the semiconductor chip via the output connection TDO of the JTAG test access port. Information can be read from the at least one shift register in a plurality of successive steps, with one bit per shift register being written in parallel to the design specific register and from there being output serially bit by bit from the semiconductor chip in each step. The JTAG test access port can be supplied with a clock signal via an input connection TCK, said clock signal being able to be used to clock the semiconductor chip in the test mode, and the JTAG test access port forwards this clock signal to the remaining components of the semiconductor chip only in particular phases. The state of a state machine in the JTAG test access port and/or the content of an instruction register in the JTAG test access port may govern(s) whether the JTAG test access port forwards the clock signal to the remaining components of the semiconductor chip.

The inventive semiconductor chip is distinguished in that the semiconductor chip is designed such that the one or more shift registers can have information read from and written to them via the JTAG test access port.

This dispenses with the need to provide each shift register with two semiconductor chip connections, which can be used exclusively for this purpose or which are normally used elsewhere, for writing and reading information to and from the shift register in question. All of the shift registers can have information written to and read from them via a single JTAG test access port, specifically regardless of the number of shift registers. This is found to be advantageous in many respects: first, the number of input and/or output connections of the semiconductor chip can be kept down, secondly semiconductor chips which are already integrated in a system can also be comprehensively tested under all circumstances, and thirdly any number of shift registers can be formed when testing the semiconductor chip, which means that each shift register can have information written to and read from it at maximum speed.

### BRIEF DESCRIPTION OF THE DRAWINGS

The invention is explained in more detail below using exemplary embodiments with reference to the Figures, in which:

FIG. 1 shows the design of a first semiconductor chip, which is described in more detail below.

FIG. 2 shows the design of a JTAG test access port of the semiconductor chip shown in FIG. 1.

FIG. 3 shows the design of a second semiconductor chip, which is described in more detail below.

FIG. 4 shows the design of a JTAG test access port of the semiconductor chip shown in FIG. 3.

FIG. 5 shows the design of a conventional semiconductor chip which can be tested using the full scan test method.

FIG. 6 shows the design of a JTAG test access port of the semiconductor chip shown in FIG. 5.

FIG. 7 shows the state diagram for a JTAG test access port based on IEEE 1149.1.

### DETAILED DESCRIPTION

The semiconductor chips described below are microcontrollers. However, they could also be another program-controlled unit, such as a microprocessor or a signal processor, for example, or any other semiconductor chip.

The text below describes a plurality of different embodiments of the type of semiconductor chip presented here. A common feature of all embodiments is that the semiconductor chip contains a multiplicity of flipflops which can be connected up to form one or more shift registers for the purpose of testing the semiconductor chip, and that the one or more shift registers can have information written to and read from it/them via a JTAG test access port of the semiconductor chip.

Before continuing, it should be pointed out that only those components of the semiconductor chips described below which are of particular interest at present are shown and described. For further details, particularly relating to the JTAG test access port, reference is made to the standard IEEE 1149.1.

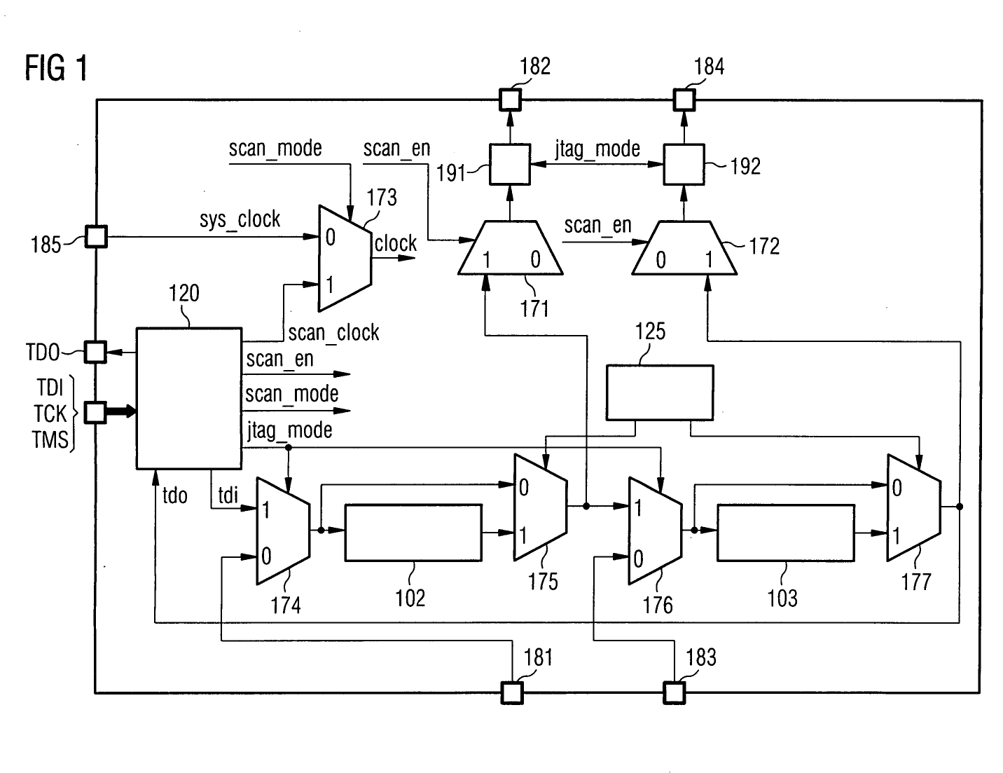

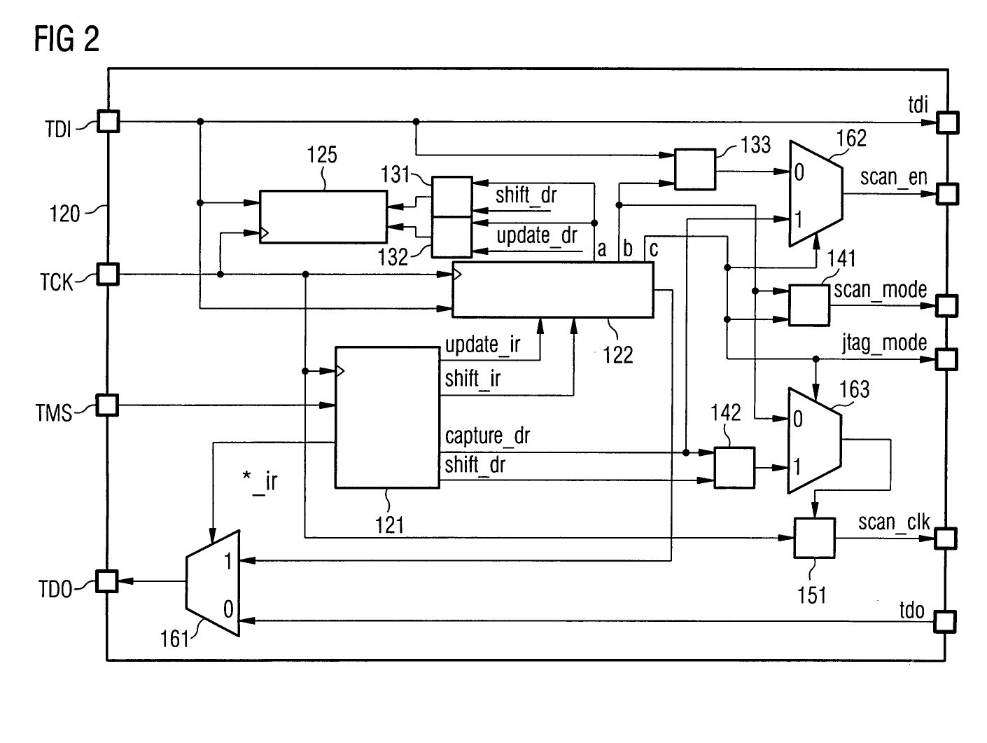

The first of the semiconductor chips presented here is illustrated in FIGS. 1 and 2.

The semiconductor chip shown in FIG. 1 contains a first multiplexer 171, a second multiplexer 172, a third multiplexer 173, a fourth multiplexer 174, a fifth multiplexer 175, a sixth multiplexer 176, a seventh multiplexer 177, a JTAG test access port 120 (subsequently called TAP), a first inhibit element 191, a second inhibit element 192 and a multiplicity of input and/or output connections, of which FIG. 1 shows only the connections TCK, TDI, TMS, TDO and 181 to 185, however.

FIG. 1 also shows a test register 125. This test register is part of the TAP 120 and is shown outside of the TAP 120 in FIG. 1, merely for the sake of clarity. As explained more precisely later, the test register in the example under consideration is formed by a shift register which stores two bits.

The semiconductor chip also contains a logic unit (not shown in FIG. 1).

In addition, the semiconductor chip may contain arbitrary further components, for example one or more CPUs, one or more memories etc.

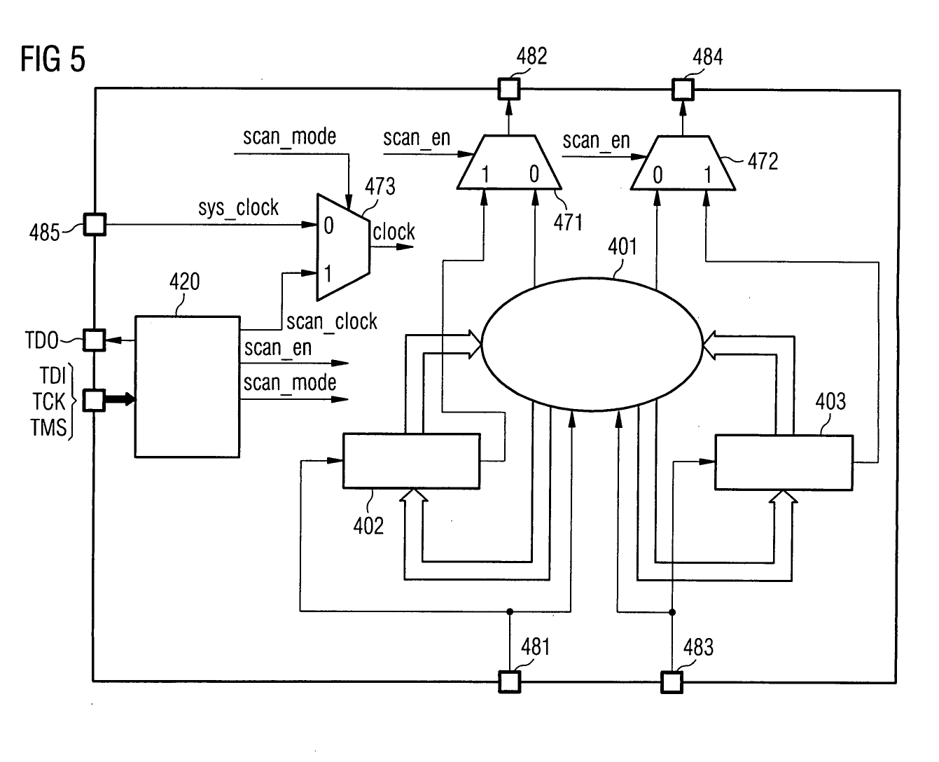

The logic unit (which is not shown in FIG. 1) corresponds to the logic unit 401 in the semiconductor chip shown in FIG. 5. The logic unit contains a multiplicity of logic gates and storage elements. In the example under consideration, the storage elements are formed by flipflops which, as in the case of the semiconductor chip shown in FIG. 5, can be connected in series, for the purpose of testing the semiconductor chip, such that they behave like a shift register. The specific way in which this happens is known and requires no further explanation. FIG. 1 shows the state of the semiconductor chip in which the flipflops of the logic unit have been connected up to form two shift registers, namely a first shift register 102 and a second shift register 103. The shift registers 102 and 103 correspond to the shift registers 402 and 403 in the semiconductor chip shown in FIG. 5.

The input side of the first shift register 102 is connected to the output connection of the multiplexer 174. The multiplexer 174 has two input connections, one of which is supplied with data tdi which are output by the TAP 120, and the other of which is connected to the input connection 181 of the semiconductor chip. The multiplexer 174 is controlled by a signal jtag_mode which is output by the TAP 120. When the signal jtag_mode is active, the multiplexer 174 outputs the data tdi, and when the signal jtag_mode is inactive, the multiplexer 174 outputs the data which are input via the input connection 181 of the semiconductor chip.

The output side of the first shift register 102 is connected to an input connection of the multiplexer 175. The multiplexer 175 has two input connections, with the second input connection being connected to the output connection of the multiplexer 174. The output connection of the multiplexer 175 is connected to one of the input connections of the multiplexer 171 and to one of the input connections of the multiplexer 176. The multiplexer 175 is controlled by the first of the bits stored in the test register 125. When the first test register bit is active, the multiplexer 175 outputs the data which are output by the shift register 102, and when the first test register bit is inactive, the multiplexer 175 outputs the data which are output by the multiplexer 174.

The multiplexer 171 forwards either the data which are output from the multiplexer 175 or data which are output from the logic unit (not shown), with the data which are output from the multiplexer 175 being either the data which are supplied to the shift register 102 or the data which are output from the shift register 102. The multiplexer 171 is controlled by a signal scan_en which is output by the TAP 120. When the signal scan_en is active, the multiplexer 171 outputs the data which are supplied to it by the multiplexer 175, and when the signal scan_en is inactive, the multiplexer 171 outputs the data which are supplied to it by the logic unit. The data which are output from the multiplexer 171 are forwarded to the output connection 182 of the semiconductor chip via the inhibit element 191.

The inhibit element 191 is controlled by the signal jtag_mode which is output by the TAP 120. The inhibit element 191 is able to prevent the signal which is output from the multiplexer 171 from being forwarded to the output connection 182. The way in which the inhibit element 191 behaves, i.e. whether or not it forwards the signal supplied to it to the output connection 182, is dependent on the level of control signal jtag_mode. When the control signal jtag_mode is active, the data supplied to the inhibit element 191 are prevented from being forwarded to the output connection 182, and when the control signal jtag_mode is inactive, the data supplied to the inhibit element 191 are forwarded to the output connection 182. The inhibit element 191 makes it possible to prevent the output connection 182 of the semiconductor chip from producing output patterns during the scan test which result in the downstream circuit being damaged.

The aforementioned multiplexer 176 has two input connections, one of which is connected to the output connection of the multiplexer 175 and the other of which is connected to the input connection 183 of the semiconductor chip. The output connection of the multiplexer 176 is connected to the input connection of the second shift register 103 and to one of the input connections of the multiplexer 177. The multiplexer 176 is controlled by the signal jtag_mode which is output by the TAP 120. When the signal jtag_mode is active, the multiplexer 176 outputs the data which are supplied to it by the multiplexer 175, and when the signal jtag_mode is inactive, the multiplexer 176 outputs the data which are input via the input connection 183 of the semiconductor chip.

The multiplexer 177 has two input connections, with the second input connection being connected to the output connection of the shift register 103. The multiplexer 177 is controlled by the second of the bits stored in the test register 125. When a second test register bit is active, the multiplexer 177 outputs the data which are output by the shift register 103, and when the second test register bit is inactive, the multiplexer 177 outputs the data which are output by the multiplexer 176. The output connection of the multiplexer 177 is connected to one of the input connections of the multiplexer 172 and to the TAP 120.

The multiplexer 172 optionally forwards the data which are output from the multiplexer 177 or data which are output from the logic unit (not shown), with the data which are output from the multiplexer 177 being either the data supplied to the shift register 103 or the data which are output from the shift register 103. The multiplexer 172 is controlled by the signal scan_en which is output by the TAP 120. When the signal scan_en is active, the multiplexer 172 outputs the data which are supplied to it by the multiplexer 177, and when the signal scan_en is inactive, the multiplexer 172 outputs the data which are supplied to it by the logic unit. The data which are output from the multiplexer 172 are forwarded to the output connection 184 of the semiconductor chip via the inhibit element 192.

The inhibit element 192 is controlled by the signal jtag_mode which is output by the TAP. The inhibit element 192 is able to prevent the signal which is output from the multiplexer 172 from being forwarded to the output connection 184. The way in which the inhibit element 192 behaves, i.e. whether or not it forwards the signal supplied to it to the output connection 184, is dependent on the level of the control signal jtag_mode. When the control signal jtag_mode is active, the data supplied to the inhibit element 192 are prevented from being forwarded to the output connection 184, and when the control signal jtag_mode is inactive, the data supplied to the inhibit element 192 are forwarded to the output connection 184. The inhibit element 192 makes it possible to prevent the output connection 184 of the semiconductor chip from producing output patterns during the scan test which result in the downstream circuit being damaged.

The multiplexer 173 has two input connections, with a first clock signal sys_clock supplied to the semiconductor chip via the input connection 185 being applied to the first input connection, and with a signal scan_clock which is output from the TAP 120 and which is used as second clock signal being applied to the second input connection. In this case, the first clock signal sys_clock is the clock signal which can be used to clock the semiconductor chip during the normal mode, and the second clock signal scan_clock is the clock signal which can be used to clock the semiconductor chip during testing of the semiconductor chip. The multiplexer 173 is controlled by the signal scan_mode which is output by the TAP 120. When the signal scan_mode is active, the clock signal scan_clock which is output by the TAP 120 is switched through, and when the signal scan_mode is inactive, the clock signal sys_clock which is supplied via the input connection 185 is switched through. The clock signal which is output from the multiplexer 173 is the clock signal which the clock-controlled components of the semiconductor chip use for operation.

The TAP 120 is a JTAG test access port based on IEEE 1149.1. As already mentioned above, the JTAG test access port based on IEEE 1149.1 was originally developed and standardized for the “boundary scan test”. In addition, the TAP 120 means that the testing of the semiconductor chip using the full scan test method or using a selective scan test method (explained in more detail later) can also be controlled using the TAP 120, and that the shift registers 102 and 103 formed when testing the semiconductor chip can have information written to and read from them via the input connection TDI of the semiconductor chip and via the TAP 120.

The TAP 120 is connected to the input connections TCK, TDI and TMS and to the output connection TDO of the semiconductor chip. The connections of the semiconductor chip, which have the TAP 120 connected to them, have the labels which are also used in the aforementioned standard IEEE 1149.1.

The TAP 120 outputs the aforementioned signals scan_clock, scan_en, scan_mode and jtag_mode and also the data tdi and is supplied with the data tdo (by the multiplexer 177).

The design of the TAP 120 is illustrated in FIG. 2. The TAP 120 contains a state machine 121, an instruction register 122, the aforementioned test register 125, AND gates 131 to 133, OR gates 141 and 142, an inhibit element 151 and multiplexers 161 to 163.

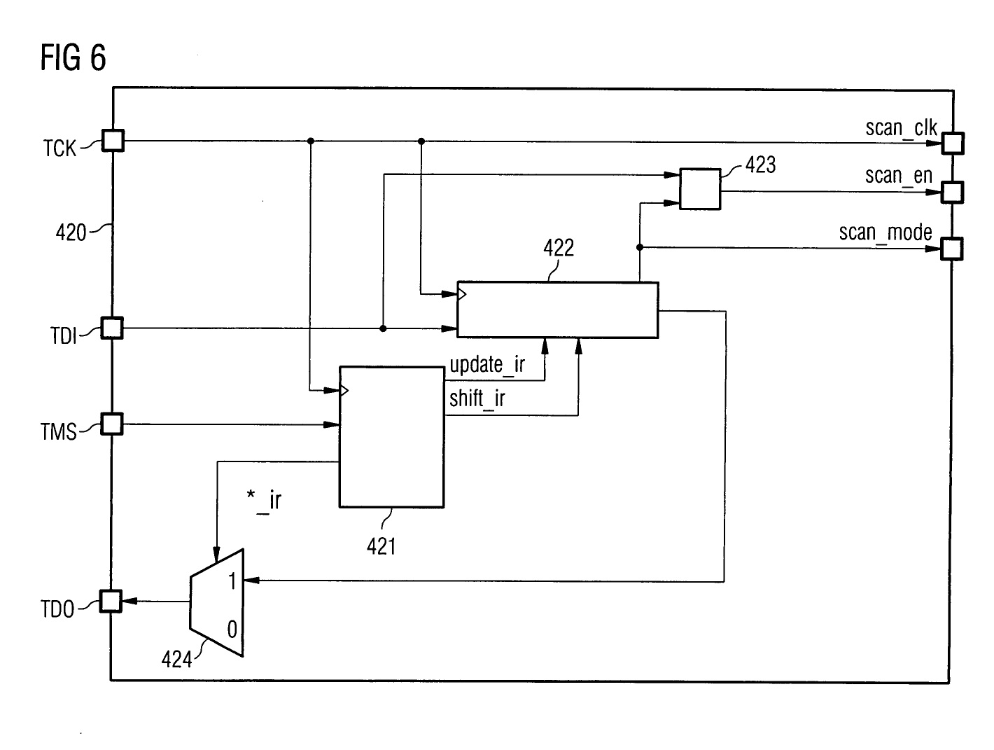

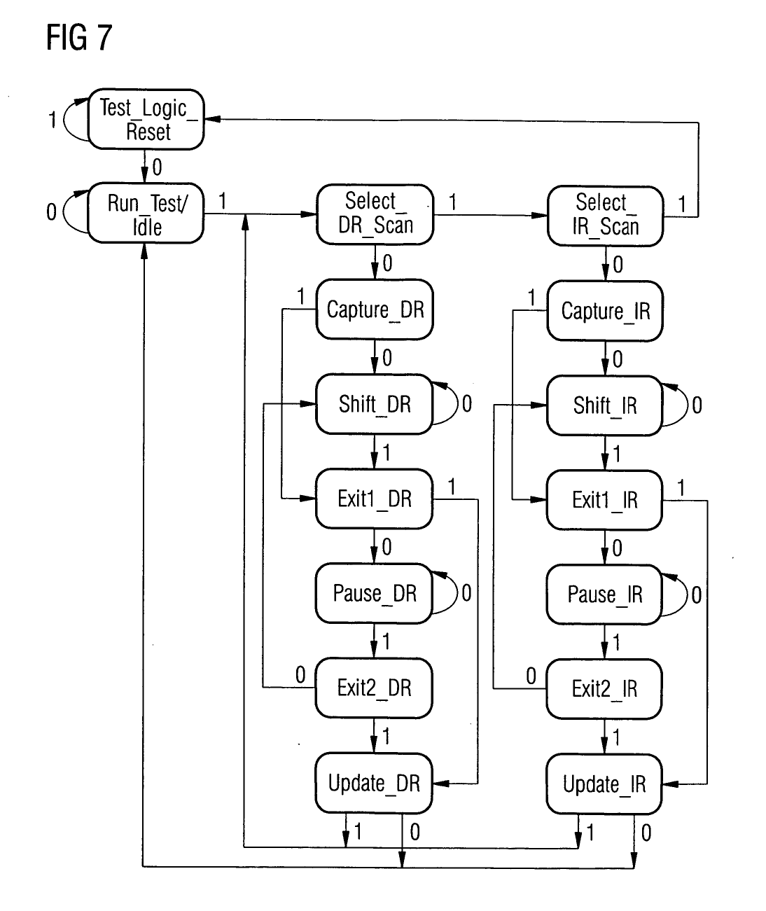

The state machine 121 is connected to the input connections TMS and TCK of the semiconductor chip and is supplied with control bits serially by the input connection TMS and with a clock signal via the input connection TCK. The state machine 121 may assume the same 16 different states as is the case for the state machine 421 of the conventional TAP 420 illustrated in FIG. 6. The state in which the state machine 121 is currently is dependent on the control bit sequence supplied to the state machine 121 via the input connection TMS. The state diagram for the state machine 121 corresponds to the state diagram shown in FIG. 7 for the state machine 421.

The state machine 121 outputs signals update_ir, shift_ir, capture_dr, shift_dr, update_dr and *_ir, where
the signal update_ir is active when the state machine is in the state update_ir,
the signal shift_ir is active when the state machine is in the state shift_ir,
the signal capture_dr is active when the state machine is in the state capture_dr,
the signal shift_dr is active when the state machine is in the state shift_dr, and
the signal update_dr is active when the state machine is in the state update_dr, and
the signal *_ir is active when the state machine is in one of the states whose label ends in _ir.

The instruction register 122 is a shift register which has a plurality of registers which are each designed to store one bit. In the example under consideration, the number of registers is three, but may also have any other greater magnitude. The instruction register 122 has an associated “shadow register” of the same size (not shown in FIG. 2).

The instruction register 122 is connected to the input connections TDI and TCK of the semiconductor chip and is supplied with instruction bits serially by the input connection TDI and with a clock signal via the input connection TCK.

The instruction register 122 is controlled by the signals update_ir and shift_ir which are output by the state machine 121. The signal update_ir prompts the parallel transfer of the data stored in the instruction register 122 into the associated shadow register. At the parallel output, it is always possible to see the content of the shadow register. The signal shift_ir prompts bit-by-bit serial data transfer from the input TDI with a simultaneous shift operation.

From the bits stored in the instruction register 122, the value of a c-th bit is used as the aforementioned signal jtag_mode and is output from the TAP 120. In the example under consideration, the c-th bit is the third bit, but in principle may also be any other bit in the instruction register 122. The c-th bit is additionally used to control the multiplexers 162 and 163 and is supplied to the OR gate 141.

The OR gate 141 is also supplied with the value of a b-th bit from the bits stored in the instruction register 122. In the example under consideration, the b-th bit is the second bit, but may in principle also be any other bit in the instruction register 122. The OR gate 141 subjects the signals supplied to it to ORing. The result of this operation is used as the aforementioned signal scan_mode and is output from the TAP 120.

The b-th bit from the bits stored in the instruction register 122 is also supplied to the AND gate 133 and to the multiplexer 163.

The AND gate 133 is also supplied with the instruction bit which is currently supplied via the input connection TDI. The AND gate 133 ANDs the signals supplied to it. The result of this ANDing is supplied to the multiplexer 162.

The multiplexer 162 is additionally supplied with the signal capture_dr which is output by the state machine 121. The multiplexer 162 is controlled by the c-th bit of the instruction register 122, as already mentioned above. When the c-th bit is active, the signal capture_dr is switched through, and when the c-th bit is inactive, the signal which is output by the AND gate 133 is switched through. The signal switched through by the multiplexer 162 is used as the aforementioned signal scan_en and is output from the TAP 120.

The multiplexer 163 is additionally supplied with the output signal from the OR gate 142. As already mentioned above, the multiplexer 163 is controlled by the c-th bit of the instruction register 122. When the c-th bit is active, the signal which is output by the OR gate 142 is switched through, and when the c-th bit is inactive, the b-th bit from the instruction register 122 is switched through. The signal which is output by the multiplexer 163 is used as control signal for the inhibit element 151.

The input side of the inhibit element 151 is connected to the input connection TCK of the semiconductor chip; the output signal from the inhibit element is the aforementioned output signal scan_clock from the TAP 120. The output signal scan_clock corresponds to the clock signal which is input via the input connection TCK. That is to say that the clock signal which is input via the input connection TCK is only routed through by the inhibit element 151. However, the inhibit element 151 is able to inhibit routing through, with the output signal from the multiplexer 163 governing how the inhibit element 151 behaves.

The OR gate 142 is supplied with the signals capture_dr and shift_dr which are output by the state machine 121. The OR gate ORs these signals and outputs the result of this logic operation to the multiplexer 163.

From the bits stored in the instruction register 122, the value of the a-th bit is supplied to the AND gate 131 and to the AND gate 132. In the example under consideration, the a-th bit is the first bit, but may in principle also be any other bit from the instruction register 122.

The AND gate 131 is additionally supplied with the signal shift_dr which is output by the state machine 121. The AND gate 131 ANDs the signals supplied to it and outputs the result of this logic operation to the test register 125.

The AND gate 132 is additionally supplied with the signal update_dr which is output by the state machine 121. The AND gate 132 ANDs the signals supplied to it and outputs the result of this logic operation to the test register 125.

The test register 125 is one of the “design specific registers” mentioned in IEEE 1149.1. It is a shift register which comprises a plurality of registers which are respectively designed to store one bit. The number of registers corresponds to the number of shift registers formed by connecting up the flipflops in a logic unit during testing of the semiconductor chip. In the example under consideration, there are two such shift registers, namely the shift registers 102 and 103, which means that the test register 125 is thus a test register comprising two registers. The test register 125 has an associated shadow register of the same size (not shown in the Figures).

The test register 125 is connected to the input connections TDI and TCK of the semiconductor chip and is supplied with instruction bits serially by the input connection TDI and with a clock signal via the input connection TCK.

The test register 125 is controlled by the signals which are output by the AND gate 131 and 132.

The x-th bit (in the example under consideration the first bit) of the test register 125 is used as the aforementioned first control signal to control the multiplexer 175, and the y-th bit (in the example under consideration the second bit) of the test register 125 is used as the aforementioned second control signal to control the multiplexer 177. In the example under consideration, the test register 125 comprises two bits, the first bit of which is the x-th bit, and the second bit of which is the y-th bit. There is no restriction to this, however. The test register 125 may also comprise more than two bits, and it is also possible to use other bits than the first bit and the second bit as the first control signal and the second control signal.

The bits shifted out of the instruction register 122 are supplied to one of the input connections of the multiplexer 161. In the example under consideration, the multiplexer 161 has two input connections, with the second input connection being supplied with the data tdo which are supplied to the TAP 120. The multiplexer 161 is controlled by the signal *_ir which is output by the state machine 121. When the signal *_ir is active, the bits shifted out of the instruction register 122 are switched through, and when the signal *_ir is inactive, the data tdo are switched through. The data which are output from the multiplexer 161 are output from the semiconductor chip via said semiconductor chip's output connection tdo. The multiplexer 161 may additionally have further input connections (not shown), which are connected to further registers of the TAP 120 (which are likewise not shown).

In addition, the data supplied to the TAP 120 via the input connection TDI of the semiconductor chip are used as the data tdi and are output from the TAP 120.

For the sake of clarity, it should be noted that although this is not shown in FIG. 2 all of the clock-controlled components of the TAP 120 are clocked by the clock signal scan_clock which is supplied to the semiconductor chip via the input connection TCK.

The semiconductor chip can be put into various modes using the TAP 120. In this case, what mode the semiconductor chip is in is determined by the bits a, b and c of the instruction register 122, inter alia. When the state machine 121 is in the state shift_ir, the instruction register 122 can have information written to it serially bit by bit, as desired, via the input connection TDI of the semiconductor chip. The state machine is put into the state shift_ir or into another desired state by inputting a corresponding bit sequence via the input connection TMS of the semiconductor chip. The appearance required for this bit sequence can be seen in the state diagram shown in FIG. 7.

When the bits a, b, c of the instruction register 122 have the values 0, 0, 0, the signals scan_en, scan_mode and jtag_mode which are output from the TAP 120 are inactive and the semiconductor chip is clocked using the clock signal sys_clock. In this state, the semiconductor chip is in the normal mode, with the normal mode being that mode which the semiconductor chip is in and operates correctly in during normal operation. In the normal mode, the semiconductor chip behaves like the conventional semiconductor chip (shown in FIGS. 5 and 6) when it is in normal mode. Preferably, the situation is such that the bits a, b, c of the instruction register 122 have the values 0, 0, 0 when the semiconductor chip has been reset. This means that the semiconductor chip is automatically in the normal mode after it has been reset.

When the bits a, b, c of the instruction register 122 have the values 0, 1, 0, the signal jtag_mode which is output from the TAP 120 is inactive, the signal scan_mode which is output from the TAP 120 is active, the signal scan_en which is output from the TAP 120 is either active or inactive, and the semiconductor chip is clocked using the clock signal scan_clock. In this state, the semiconductor chip is in a full scan test mode, the full scan test mode being that mode in which the semiconductor chip can be tested using the full scan test method. In this case, the semiconductor chip is tested using the full scan test method in exactly the same way as is the case with the conventional semiconductor chip shown in FIGS. 5 and 6. That is to say that the TAP 120 is first put into a state, by inputting appropriate data via the input connection TDI, in which the signal scan_en which is output by the TAP 120 has the value which connects up the flipflops of the logic unit to form the shift registers 102 and 103. In this state, the semiconductor chip is in the full scan test/shift mode. The full scan test/shift mode of the semiconductor chip shown in FIGS. 1 and 2 corresponds to the full scan test/shift mode of the semiconductor chip shown in FIGS. 5 and 6. Next, the shift registers 102 and 103 have data representing a test pattern written to them serially bit by bit via the input connections 181 and 183 of the semiconductor chip. When this has happened, the semiconductor chip is briefly, for example for one or two clock cycles of the clock signal scan_clock, put into the full scan test/capture mode via the input connection TDI of the semiconductor chip. The full scan test/capture mode of the semiconductor chip shown in FIGS. 1 and 2 corresponds to the full scan test/capture mode of the conventional semiconductor chip shown in FIGS. 5 and 6. That is to say that in this mode the shift registers 102 and 103 are cleared, and the logic unit, including the flipflops, operates as in the normal mode. Only the clock signal (scan_clock) is different than in the normal mode (sys_clock). In the full scan test/capture mode, the data stored by the flipflops may change. Whether and, if appropriate, how they change is dependent, inter alia, on the data which were loaded into the shift registers 102 and 103 beforehand and on the design and operation of the logic unit. Next, the semiconductor chip is put back into the full scan test/shift mode via the input connection TDI. In this state, the data stored in the shift registers 102 and 103 are read via the output connections 182 and 184 of the semiconductor chip. At the same time or thereafter, it is already possible to write data representing another test pattern to the shift registers 102 and 103. The data which are read from the shift registers 102 and 103 are then compared with prescribed nominal data. The nominal data are those data which ought to be stored in the shift registers 102 and 103 if the semiconductor chip is operating correctly. The result of the comparison between the data which are read from the shift registers 102 and 103 and the nominal data can thus be used to ascertain whether the semiconductor chip is operating correctly. If the data compared with one another match, it may be assumed that the semiconductor chip has operated correctly. If the data do not match, the semiconductor chip has not operated correctly. The test described above can be repeated as often as desired using other test patterns.

When the bits a, b, c of the instruction register 122 have the values 1, 0, 0, the signals scan_mode and jtag_mode which are output from the TAP 120 are inactive and the semiconductor chip is clocked using the clock signal sys_clock. In this state, the semiconductor chip is in a test register access mode, in which it is possible to change the content of the test register 125 via the input connection TDI of the semiconductor chip under the control of the control bit sequence which is input via the input connection TMS of the semiconductor chip. So that the content of the test register 125 can actually be changed, it is additionally necessary for the signal shift_dr which is output by the TAP 120 to be active.

When the bits a, b, c of the instruction register 122 have the values 0, 1, 1, the signals scan_mode and jtag_mode which are output from the TAP 120 are active, the signal scan_en which is output from the TAP 120 is either active or inactive, and the semiconductor chip is clocked using the clock signal scan_clock, with the clock signal scan_clock being output from the TAP 120 only intermittently, however, to be more precise only in the phases in which either the signal capture_dr which is output by the state machine 121 or the signal shift_dr which is output by the state machine 121 is active. When the bits a, b, c of the instruction register 122 have the values 0, 1, 1, the semiconductor chip is in the selective scan test mode. In the selective scan test mode, it is possible to test the semiconductor chip using the scan method, as in the case of the full scan test mode. The selective scan test mode has two particular features in comparison with the full scan test mode, however:
first, the test patterns which are to be written to the shift registers 102 and 103 are written to the shift registers 102 and 103 via the input connection TDI of the semiconductor chip, and the data which are read from the shift registers 102 and 103 are output from the semiconductor chip via the output connection TDO of the semiconductor chip, and
secondly, the scan test can be performed either by exclusively using the shift register 102 or by exclusively using the shift register 103 or by using both the shift register 102 and the shift register 103.

Whether the scan test is carried out by exclusively using the shift register 102 or by exclusively using the shift register 103 or by using both the shift register 102 and the shift register 103 is dependent on the content of the test register 125. To be more precise, the scan test is carried out by exclusively using the shift register 102 if the (first) bit of the test register 125, which bit controls the multiplexer 175, is active and the (second) bit of the test register 125, which bit controls the multiplexer 177, is inactive, the scan test is carried out by exclusively using the shift register 103 if the (first) bit of the test register 125, which bit controls the multiplexer 175, is inactive and the (second) bit of the test register 125, which bit controls the multiplexer 177, is active, and
the scan test is carried out using both the shift register 102 and the shift register 103 if the (first) bit of the test register 125, which bit controls the multiplexer 175, is active and the (second) bit of the test register 125, which bit controls the multiplexer 177, is likewise active.

The way in which the test register 125 has the bits controlling the multiplexers 175 and 177 written to it has already been mentioned above during the explanation of the test register access mode.

Regardless of which shift register(s) need(s) to have a test pattern written to it/them, the test pattern, to be more precise a bit sequence representing the test pattern, is input via the input connection TDI of the semiconductor chip. The data which are input via the input connection TDI pass through the TAP 120 and are output therefrom unchanged as data tdi. The data tdi are forwarded to one of the input connections of the multiplexer 174 and, since the signal jtag_mode is active in the selective scan test mode, are switched through by the multiplexer 174. The data tdi therefore reach the input connection of the shift register 102 (and one of the input connections of the multiplexer 175).

Before starting to write a test pattern to the shift register 102 and/or 103, the aforementioned settings are first made in the test register 125, and these stipulate whether the semiconductor chip test is to be performed by exclusively using the shift register 102 or by exclusively using the shift register 103 or using both the shift register 102 and the shift register 103. Likewise before a test pattern is actually written to the shift register 102 and/or 103, it is additionally necessary to ensure that the signal scan_en is active, because only then are the flipflops in the logic unit connected up to form the shift registers 102 and 103. The signal scan_en is active when the state machine 121 is not in the state capture_dr. Preferably, the test pattern is written to the shift register when the state machine 121 is in the state shift_dr, because in this state the TAP 120 also outputs the clock signal scan_clock which can be used as a shift clock. When the semiconductor chip is in the selective scan test mode and the state machine 121 is in the state shift_dr, it is possible to write a test pattern to the shift registers 102 and/or 103. This state is subsequently called the selective scan test/shift mode.

When the semiconductor chip is in the selective scan test/shift mode and the test register 125 contains the setting that the semiconductor chip test needs to be carried out by exclusively using the shift register 102, the data which are to be written to the shift register 102 are input via the input connection TDI, are forwarded from there via the TAP 120 and the multiplexer 174 to the shift register 102, and are stored in the latter.

When the semiconductor chip is in the selective scan test/shift mode and the test register 125 contains the setting that the semiconductor chip test is to be carried out by exclusively using the shift register 103, the data which are to be written to the shift register 103 are input via the input connection TDI, are forwarded from there via the TAP 120, the multiplexer 174, the multiplexer 175 and the multiplexer 176 to the shift register 103 and are stored in the latter.

When the semiconductor chip is in the selective scan test/shift mode and the test register 125 contains the setting that the semiconductor chip test is to be carried out using both the shift register 102 and the shift register 103, first the data which are to be written to the shift register 103 and immediately thereafter the data which are to be written to the shift register 102 are input into the semiconductor chip via the latter's input connection TDI, and from there are forwarded via the TAP 120 and the multiplexer 174 to the shift register 102. The shift register 102 stores the data supplied to it, with each storage operation involving the bit stored in the last memory cell of the shift register 102 being shifted out of the shift register 102. The bits shifted out of the shift register 102 are forwarded via the multiplexers 175 and 176 to the shift register 103, which stores the data supplied to it. When the last of the data items which are input via the input connection TDI of the semiconductor chip has been stored in the shift register 102, the data which are written to the shift register 102 first, that is to say the data intended for the shift register 103, are shifted out of the shift register 103 entirely and are stored in the shift register 102, and the data which are written to the shift register 102 last, that is to say the data intended for the shift register 102, are stored in the shift register 102.

When the test pattern to be used has been written to the shift register 102 and/or to the shift register 103, the semiconductor chip is briefly put into a selective scan test/capture mode. In the example under consideration, this is done by virtue of the state machine 121 in the TAP 120 being put into the state capture_dr by inputting appropriate data via the input connection TMS of the semiconductor chip. The result of this is that the signal scan_en becomes inactive, and this in turn results in the shift registers 102 and 103 being cleared. In the state capture_dr, the clock signal scan_clock is also output from the TAP 120. In this state of the semiconductor chip, the logic unit in the semiconductor chip, including the flipflops, operates as in the normal mode. Only the clock signal used (scan_clock) is different than in the normal mode (sys_clock). The semiconductor chip is generally kept in the selective scan test/capture mode only briefly, for example for one or two clock cycles of the clock signal scan_clock. During this time, the data stored by the flipflops may change. Whether and, if appropriate, how they change is dependent, inter alia, on the data which were loaded into the shift registers 102 and 103 beforehand and on the design and operation of the logic unit.

Next, the semiconductor chip is put back into the selective scan test/shift mode. In the example under consideration, this is done by virtue of the state machine 121 of the TAP 120 being put back into the state shift_dr by inputting appropriate data via the input connection TMS of the semiconductor chip. In this state, the data stored in the shift registers 102 and 103 are read and are output from the semiconductor chip via the latter's output connection TDO.

When the semiconductor chip is in the selective scan test/shift mode and the test register 125 contains the setting that the semiconductor chip test is to be carried out by exclusively using the shift register 102, the data stored in the shift register 102 are shifted out of the shift register 102 and are forwarded to the output connection TDO via the multiplexers 175, 176, 177 and the TAP 120.

When the semiconductor chip is in the selective scan test/shift mode and the test register 125 contains the setting that the semiconductor chip test is to be carried out by exclusively using the shift register 103, the data stored in the shift register 103 are shifted out of the shift register 103 and are forwarded to the output connection TDO via the multiplexer 177 and the TAP 120.

When the semiconductor chip is in the selective scan test/shift mode and the test register 125 contains the setting that the semiconductor chip test is to be carried out using both the shift register 102 and the shift register 103,
the data stored in the shift register 103 are shifted out of the shift register 103 and are forwarded to the output connection TDO via the multiplexer 177 and the TAP 120, and
the data stored in the shift register 102 are shifted out of the shift register 102, are supplied to the shift register 103 via the multiplexers 175 and 176, are buffer-stored in the shift register 103, and then are shifted out of the shift register 103 and forwarded to the output connection TDO via the multiplexer 177 and the TAP 120,
   with the shifting of the data stored in the shift register 103 out of the shift register 103 and the storage of the data coming from the shift register 102 in the shift register taking place synchronously, so that first the data coming from the shift register 103 and immediately thereafter the data coming from the shift register 102 are output from the semiconductor chip.

At the same time as the data stored in the shift register are read or thereafter, it is already possible to write data representing another test pattern to the shift registers 102 and/or 103.

The data which are read from the shift registers 102 and/or 103 are then compared with prescribed nominal data. The nominal data are those data which ought to be stored in the shift registers 102 and/or 103 if the semiconductor chip is operating correctly. The result of the comparison between the data which are read from the shift registers 102 and/or 103 and the nominal data can thus be used to ascertain whether the semiconductor chip is operating correctly. If the data compared with one another match, it may be assumed that the semiconductor chip has operated correctly. If the data do not match, the semiconductor chip has not operated correctly.

The test described above can be repeated as often as desired using other test patterns.

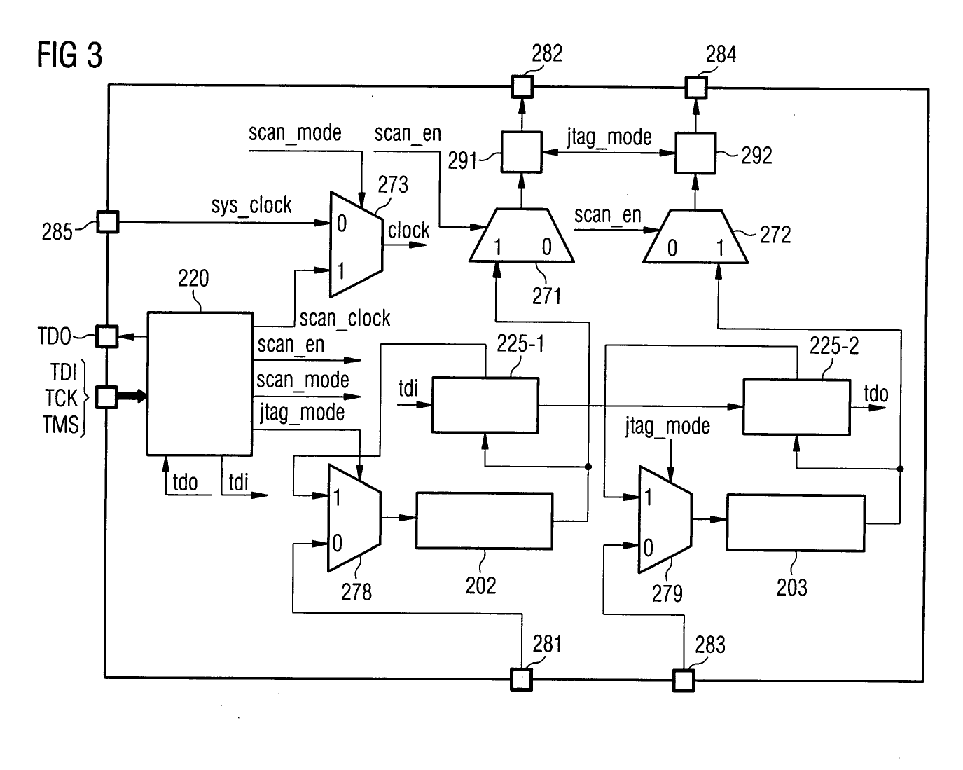

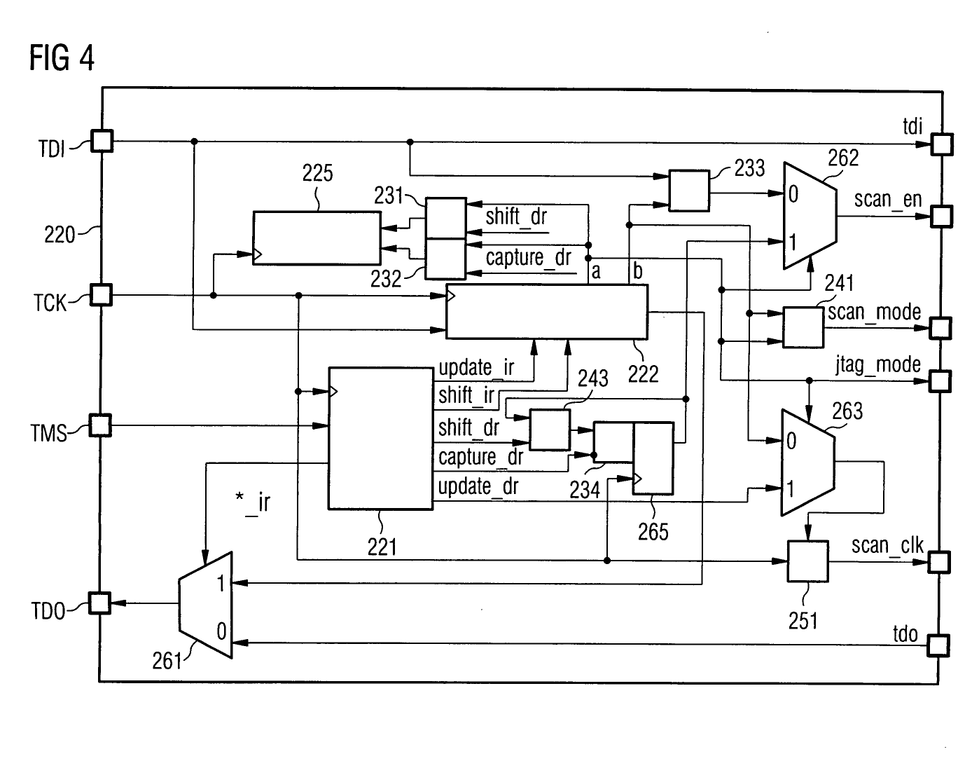

A further semiconductor chip which can be tested using the scan method is shown in FIGS. 3 and 4 and is described below with reference thereto.

The semiconductor chip shown in FIG. 3 contains a first multiplexer 271, a second multiplexer 272, a third multiplexer 273, a fourth multiplexer 278, a fifth multiplexer 279, a JTAG test access port 220 (subsequently called TAP), a first inhibit element 291, a second inhibit element 292 and a multiplicity of input and/or output connections, of which only the connections TCK, TDI, TMS, TDO and 281 to 285 are shown in FIG. 3, however.

FIG. 3 also shows two registers 225-1 and 225-2 connected up to form a shift register. This shift register is part of the TAP 220, to be more precise a test register 225 in the TAP 220 (see FIG. 4), and is shown outside of the TAP 220 in FIG. 3, merely for the sake of clarity. The shift register 225 is supplied with data tdi and outputs data tdo. The registers 225-1 and 225-2 forming the shift register are each designed to store one bit. The test register 225 does not have an associated shadow register.

The semiconductor chip also contains a logic unit (not shown in FIG. 3).

In addition, the semiconductor chip may contain any other components, for example one or more CPUs, one or more memories etc.

The logic unit (not shown in FIG. 3) corresponds to the logic unit 401 in the semiconductor chip shown in FIG. 5. The logic unit contains a multiplicity of logic gates and storage elements. In the example under consideration, the storage elements are formed by flipflops which, as in the case of the semiconductor chip shown in FIG. 5, can be connected in series, for the purpose of testing the semiconductor chip, such that they behave like a shift register. The specific way in which this happens is known and requires no further explanation. FIG. 3 shows the state of the semiconductor chip in which the flipflops of the logic unit are connected up to form two shift registers, namely a first shift register 202 and a second shift register 203. The shift registers 202 and 203 correspond to the shift registers 402 and 403 in the conventional semiconductor chip shown in FIG. 5.

The input side of the first shift register 202 is connected to the output connection of the multiplexer 278. The multiplexer 278 has two input connections, one of which is supplied with the bit stored in the register 225-1 and the other of which is connected to the input connection 281 of the semiconductor chip. The multiplexer 278 is controlled by a signal jtag_mode which is output by the TAP 220. When the signal jtag_mode is active, the multiplexer 278 outputs the bit stored in the register 225-1, and when the signal jtag_mode is inactive, the multiplexer 278 outputs the data which are input via the semiconductor chip's input connection 281.

The output side of the first shift register 202 is connected to an input connection of the register 225-1 and to an input connection of the multiplexer 271.

The multiplexer 271 forwards either the data which are output from the shift register 202 or data which are output from the logic unit (not shown). The multiplexer 271 is controlled by a signal scan_en which is output by the TAP 220. When the signal scan_en is active, the multiplexer 271 outputs the data supplied to it by the shift register 202, and when the signal scan_en is inactive, the multiplexer 271 outputs the data supplied to it by the logic unit. The data which are output from the multiplexer 271 are forwarded to the output connection 282 of the semiconductor chip via the inhibit element 291.

The inhibit element 291 is controlled by the signal jtag_mode which is output by the TAP 220. The inhibit element 291 is able to prevent the signal which is output from the multiplexer 271 from being forwarded to the output connection 282. The way in which the inhibit element 291 behaves, i.e. whether or not it forwards the signal supplied to it to the output connection 282, is dependent on the level of control signal jtag_mode. When the control signal jtag_mode is active, the data supplied to the inhibit element 291 are prevented from being forwarded to the output connection 282, and when the control signal jtag_mode is inactive, the data supplied to the inhibit element 291 are forwarded to the output connection 282. The inhibit element 291 is able to prevent the output connection 282 of the semiconductor chip from producing output patterns during the scan test which result in the downstream circuit being damaged.

The input side of the second shift register 203 is connected to the output connection of the multiplexer 279. The multiplexer 279 has two input connections, one of which is supplied with the bit stored in the register 225-2 and the other of which is connected to the input connection 283 of the semiconductor chip. The multiplexer 279 is controlled by the signal jtag_mode which is output by the TAP 220. When the signal jtag_mode is active, the multiplexer 279 outputs the bit stored in the register 225-2, and when the signal jtag_mode is inactive, the multiplexer 279 outputs the data which are input via the semiconductor chip's input connection 283.

The output side of the second shift register 203 is connected to an input connection of the register 225-2 and to an input connection of the multiplexer 272.

The multiplexer 272 forwards either the data which are output from the shift register 203 or data which are output from the logic unit (not shown). The multiplexer 272 is controlled by the signal scan_en which is output by the TAP 220. When the signal scan_en is active, the multiplexer 272 outputs the data supplied to it by the shift register 203, and when the signal scan_en is inactive, the multiplexer 272 outputs the data supplied to it by the logic unit. The data which are output from the multiplexer 272 are forwarded to the output connection 284 of the semiconductor chip via the inhibit element 292.

The inhibit element 292 is controlled by the signal jtag_mode which is output by the TAP 220. The inhibit element 291 is able to prevent the signal which is output from the multiplexer 272 from being forwarded to the output connection 284. The way in which the inhibit element 292 behaves, i.e. whether or not it forwards the signal supplied to it to the output connection 284, is dependent on the level of the control signal jtag_mode. When the control signal jtag_mode is active, the data supplied to the inhibit element 292 are prevented from being forwarded to the output connection 284, and when the control signal jtag_mode is inactive, the data supplied to the inhibit element 292 are forwarded to the output connection 284. The inhibit element 292 can prevent the output connection 284 of the semiconductor chip from producing output patterns during the scan test which result in the downstream circuit being damaged.

The multiplexer 273 has two input connections, with a first clock signal sys_clock supplied to the semiconductor chip via the input connection 285 being applied to the first input connection, and with a signal scan_clock which is output from the TAP 220 and which is used as second clock signal being applied to the second input connection. In this case, the first clock signal sys_clock is the clock signal which can be used to clock the semiconductor chip during normal operation, and the second clock signal scan_clock is the clock signal which can be used to clock the semiconductor chip during testing of the semiconductor chip. The multiplexer 273 is controlled by the signal scan_mode which is output by the TAP 220. When the signal scan_mode is active, the clock signal scan_clock which is output by the TAP 220 is switched through, and when the signal scan_mode is inactive, the clock signal sys_clock which is supplied via the input connection 285 is switched through. The clock signal which is output from the multiplexer 273 is the clock signal which the clock-controlled components of the semiconductor chip use for operation.

The TAP 220 is a JTAG test access port based on IEEE 1149.1. As already mentioned above, the JTAG test access port based on IEEE 1149.1 was originally developed and standardized for the “boundary scan test”. In addition, the TAP 220 means that it is also possible for the testing of the semiconductor chip using the full scan test method or a serial scan test method (explained in more detail later) to be controlled using the TAP 120, and that the shift registers 202 and 203 formed when testing the semiconductor chip can have information written to and read from them via the semiconductor chip's input connection TDI and the TAP 220.

The TAP 220 is connected to the input connections TCK, TDI and TMS and to the output connection TDO of the semiconductor chip. The connections of the semiconductor chip, which have the TAP 220 connected to them, have the labels which are also used in the aforementioned standard IEEE 1149.1.

The TAP 220 outputs the aforementioned signals scan_clock, scan_en, scan_mode and jtag_mode and also the data tdi and is supplied with the data tdo (by the register 225-2).

The design of the TAP 220 is illustrated in FIG. 4. The TAP 220 contains a state machine 221, an instruction register 222, the aforementioned test register 225, AND gates 231 to 234, OR gates 241 and 243, an inhibit element 251, multiplexers 261 to 263 and a flipflop 265.

The state machine 221 is connected to the input connections TMS and TCK of the semiconductor chip and is supplied with control bit serially via the input connection TMS and with a clock signal via the input connection TCK. The state machine 221 may assume the same 16 different states as is the case for the state machine 421 in the conventional TAP 420 illustrated in FIG. 6. What state the state machine 221 is currently in is dependent on the control bit sequence supplied to the state machine 221 via the input connection TMS. The state diagram for the state machine 221 corresponds to the state diagram shown in FIG. 7 for the state machine 421.

The state machine 221 outputs signals update_ir, shift_ir, capture_dr, shift_dr, update_dr and *_ir, where
the signal update_ir is active when the state machine is in the state update_ir,
the signal shift_ir is active when the state machine is in the state shift_ir,
the signal capture_dr is active when the state machine is in the state capture_dr,
the signal shift_dr is active when the state machine is in the state shift_dr, and
the signal update_dr is active when the state machine is in the state update_dr, and
the signal *_ir is active when the state machine is in one of the states whose label ends in _ir.

The instruction register 222 is a shift register which comprises a plurality of registers which are each designed to store 1 bit. The number of registers in the example under consideration is two, but may also be of any greater magnitude. The instruction register 222 has an associated shadow register of the same size (not shown in FIG. 4).

The instruction register 222 is connected to the input connections TDI and TCK of the semiconductor chip and is supplied with instruction bits serially via the input connection TDI and with a clock signal via the input connection TCK.

The instruction register 222 is controlled by the signals update_ir and shift_ir which are output by the state machine 221. The signal update_ir prompts the parallel transfer of the data stored in the instruction register 222 into the shadow register, and the signal shift_ir prompts bit-by-bit serial transfer of data into the instruction register 222 with a simultaneous shift operation.

The signal update_ir determines whether an instruction bit supplied to the instruction register 222 via the input connection TDI is transferred into the instruction register, and the signal shift_ir determines whether the content of the instruction register 222 is shifted.

From the bits stored in the instruction register 222, the value of an a-th bit is used as the aforementioned signal jtag_mode and is output from the TAP 220. In the example under consideration, the a-th bit is the first bit, but may in principle also be any other bit of the instruction register 222. In addition, the a-th bit is used to control the multiplexers 262 and 263 and is supplied to the OR gate 241 and to the AND gates 231 and 232.

The OR gate 241 is also supplied with the value of a b-th bit from the bits stored in the instruction register 222. In the example under consideration, the b-th bit is the second bit, but may in principle also be any other bit of the instruction register 222. The OR gate 241 subjects the signals supplied to it to an OR operation. The result of this operation is used as the aforementioned signal scan_mode and is output from the TAP 120.

The b-th bit from the bits stored in the instruction register 222 is also supplied to the AND gate 233 and to the multiplexer 263.

The AND gate 233 is also supplied with the instruction bit which is currently supplied via the input connection TDI. The AND gate 233 ANDs the signals supplied to it. The result of this ANDing is supplied to the multiplexer 262.

The multiplexer 262 is additionally supplied with the output signal from the flipflop 265. As already mentioned above, the multiplexer 162 is controlled by the a-th bit of the instruction register 222. When the a-th bit is active, the output signal from the flipflop 265 is switched through, and when the a-th bit is inactive, the signal which is output by the AND gate 233 is switched through. The signal switched through by the multiplexer 262 is used as the aforementioned signal scan_en and is output from the TAP 220.

The input connection of the flipflop 265 is connected to the output connection of the AND gate 234 and is clocked by the clock signal supplied to the TAP 220 via the semiconductor chip's input connection TCK.

As input signals, the AND gate 234 is supplied with the output signal from the OR gate 243 and with the inverted output signal capture_dr from the state machine 221. The AND gate 234 subjects the signals supplied to it to logic ANDing and outputs the result of this ANDing to the flipflop 265.

As input signals, the OR gate 243 is supplied with the output signal from the flipflop 265 and with the output signal shift_dr from the state machine 221. The OR gate 243 subjects the signals supplied to it to logic ORing and outputs the result of this ORing to the AND gate 234.

The multiplexer 263 is additionally supplied with the output signal update_dr from the state machine 221. As already mentioned above, the multiplexer 263 is controlled by the a-th bit of the instruction register 222. When the a-th bit is active, the signal update_dr is switched through, and when the a-th bit is inactive, the b-th bit of the instruction register 222 is switched through. The signal which is output by the multiplexer 263 is used as control signal for the inhibit element 251.

The input side of the inhibit element 151 is connected to the input connection TCK of the semiconductor chip; the output signal from the inhibit element is the aforementioned output signal scan_clock from the TAP 220. The output signal scan_clock corresponds to the clock signal which is input via the input connection TCK. That is to say that the clock signal which is input via the input connection TCK is only switched through by the inhibit element 251. However, the inhibit element 251 can inhibit switching through, with the output signal from the multiplexer 163 governing how the inhibit element 251 behaves.

As already mentioned above, the value of the a-th bit from the bits stored in the instruction register 222 is also supplied to the AND gate 231 and to the AND gate 232.

The AND gate 231 is additionally supplied with the signal shift_dr which is output by the state machine 221. The AND gate 231 ANDs the signals supplied to it and outputs the result of this logic operation to the test register 225.

The AND gate 232 is additionally supplied with the signal capture_dr which is output by the state machine 221. The AND gate 232 ANDs the signals supplied to it and outputs the result of this logic operation to the test register 225.

The test register 225 is one of the “design specific registers” mentioned in IEEE 1149.1. It is a shift register which comprises a plurality of registers which are each designed to store one bit. The number of registers corresponds to the number of shift registers formed by connecting up the flipflops of the logic unit during testing of the semiconductor chip. In the example under consideration, there are two such shift registers, namely the shift registers 202 and 203, which means that the test register 225 is thus a test register comprising two registers. The registers in the test register 225 can also have information written to and read from them in parallel and without a shift operation.

The test register 225 is connected to the input connections TDI and TCK of the semiconductor chip and is supplied with instruction bits serially via the input connections TDI and with a clock signal via the input connection TCK.

The test register 225 is controlled by the signals which are output by the AND gates 231 and 232.

The bits shifted out of the instruction register 222 are supplied to one of the input connections of the multiplexer 261. In the example under consideration, the multiplexer 261 has two input connections, with the second input connection being supplied with the data tdo which are supplied to the TAP 220. The multiplexer 261 is controlled by the signal *_ir which is output by the state machine 221. When the signal *_ir is active, the bits shifted out of the instruction register 222 are switched through, and when the signal *_ir is inactive, the data tdo are switched through. The data which are output from the multiplexer 261 are output from the semiconductor chip via the latter's output connection TDO. The multiplexer 261 may additionally have further input connections (not shown) which are connected to further registers in the TAP 220 (which are likewise not shown).

In addition, the data supplied to the TAP 220 via the semiconductor chip's input connection TDI are used as the data tdi and are output from the TAP 220.

For the sake of completeness, it should be noted that, although not shown in FIG. 4, all clock-controlled components of the TAP 220 are clocked by the clock signal scan_clock supplied to the semiconductor chip via the input connection TCK.

The semiconductor chip may be put into various modes via the TAP 220. What mode the semiconductor chip is in is then determined by the bits a and b of the instruction register 222, inter alia. The instruction register 222 can have information written to it via the semiconductor chip's input connection TDI in the state shift_ir of the state machine 221. The state machine is put into the state shift_ir or into another desired state by inputting an appropriate bit sequence via the semiconductor chip's input connection TMS. The appearance which this bit sequence needs to have can be found in the state diagram shown in FIG. 7.

When the bits a, b of the instruction register 222 have the values 0, 0, the signals scan_en, scan_mode and jtag_mode which are output from the TAP 120 are inactive, and the semiconductor chip is clocked using the clock signal sys_clock. In this state, the semiconductor chip is in the normal mode, the normal mode being that mode which the semiconductor chip is in and operates correctly in during normal operation. In the normal mode, the semiconductor chip behaves like the conventional semiconductor chip shown in FIGS. 5 and 6 when it is in the normal mode. Preferably, the bits a, b of the instruction register 222 have the values 0, 0 after the semiconductor chip is reset. This means that the semiconductor chip is automatically in the normal mode after it has been reset.

When the bits a, b of the instruction register 222 have the values 0, 1, the signal jtag_mode which is output from the TAP 220 is inactive, the signal scan_mode which is output from the TAP 220 is active, the signal scan_en which is output from the TAP 220 is either active or inactive, and the semiconductor chip is clocked using the clock signal scan_clock. In this state, the semiconductor chip is in the full scan test mode, the full scan test mode being that mode in which the semiconductor chip can be tested using the full scan test method. In this case, the semiconductor chip is tested using the full scan test method in exactly the same way as is the case with the conventional semiconductor chip shown in FIGS. 5 and 6. That is to say that appropriate data are input via the input connection TDI in order to put the TAP 220 first of all into a state in which the signal scan_en which is output by the TAP 220 has the value which connects up the flipflops in the logic unit to form the shift registers 202 and 203. In this state, the semiconductor chip is in the full scan test/shift mode. The full scan test/shift mode of the semiconductor chip shown in FIGS. 1 and 2 corresponds to the full scan test/shift mode of the conventional semiconductor chip shown in FIGS. 5 and 6. Next, the shift registers 202 and 203 have data representing a test pattern written to them serially bit by bit via the semiconductor chip's input connections 181 and 183. When this has been done, the semiconductor chip is briefly, for example for one or two clock cycles of the clock signal scan_clock, put into the full scan test/capture mode via the semiconductor chip's input connection TDI. The signal which is to be input via the input connection TDI for this purpose is a signal which prompts inversion of the signal scan_en which is output from the TAP 220, that is to say a signal which is the complement of the signal which is input during the full scan test/shift mode. The full scan test/capture mode of the semiconductor chip shown in FIGS. 1 and 2 corresponds to the full scan test/capture mode of the conventional semiconductor chip shown in FIGS. 5 and 6. That is to say that in this mode the shift registers 202 and 203 are cleared, and the logic unit, including the flipflops, operates as in the normal mode. Only the clock signal (scan_clock) is different than in the normal mode (sys_clock). In the full scan test/capture mode, the data stored by the flipflops may change. Whether and, if appropriate, how they change is dependent, inter alia, on the data which were loaded into the shift registers 202 and 203 beforehand and on the design and operation of the logic unit. After that, the semiconductor chip is put back into the full scan test/shift mode via the input connection TDI. In this state, the data stored in the shift registers 202 and 203 are read via the semiconductor chip's output connections 282 and 284. At the same time or thereafter, it is already possible to write data representing another test pattern to the shift registers 202 and 203. The data which are read from the shift registers 202 and 203 are then compared with prescribed nominal data. The nominal data are those data which ought to be stored in the shift registers 202 and 203 if the semiconductor chip is operating correctly. The result of the comparison between the data which are read from the shift registers 202 and 203 and the nominal data can thus be used to ascertain whether the semiconductor chip is operating correctly. If the data compared with one another match, then it may be assumed that the semiconductor chip has operated correctly. If the data do not match, the semiconductor chip has not operated correctly. The test described above can be repeated as often as desired using other test patterns.

When the bits a, b of the instruction register 122 have the values 1, 1, the signals scan_mode and jtag_mode which are output from the TAP 220 are active, the signal scan_en which is output from the TAP 120 is either active or inactive, and the semiconductor chip is clocked using the clock signal scan_clock, with the clock signal scan_clock being output from the TAP 220 only intermittently, to be more precise only in the phases in which the signal update_dr which is output by the state machine 221 is active, however. When the bits a, b of the instruction register 122 have the values 1, 1, the semiconductor chip is in the serial scan test mode. In the serial scan test mode, it is possible to test the semiconductor chip using the scan method, as in the case of the full scan test mode. In comparison with the full scan test mode, however, the serial scan test mode has the particular features that the test patterns which are to be written to the shift registers 202 and 203 are written to the shift registers 202 and 203 via the semiconductor chip's input connection TDI and the test register 225, and that the data shifted out of the shift registers 202 and 203 are output from the semiconductor chip via the test register 225 and the semiconductor chip's output connection TDO.

To write test patterns to the shift registers 202 and 203, the test patterns, to be more precise a bit sequence representing the test patterns, are input serially bit by bit via the semiconductor chip's input connection TDI and are stored in the test register 225 of the TAP 220.

Before actually starting to write the test patterns to the test register 225, but no later than before the data stored in the test register 225 are subsequently transferred into the shift registers 202 and 203, it is also necessary for the semiconductor chip shown in FIGS. 3 and 4 to have the assurance that the signal scan_en is active, because only then are the flipflops in the logic unit connected up to form the shift registers 202 and 203. The signal scan_en is active when
either the state machine 221 is in the state shift_dr or the output signal from the flipflop 265 is equal to “1” and when, at the same time,
the state machine 221 is not in the state capture_dr.

That is to say that the signal scan_en is activated by putting the state machine 221 into the state shift_dr and is deactivated by putting the state machine 221 into the state capture_dr.

In the example under consideration, the data to be written to the shift register 225 are input via the semiconductor chip's input connection TDI in the state shift_dr of the state machine 221. In this state, the signal scan_en is automatically already active while the test patterns or a portion thereof are being written to the test register 225.

In the example under consideration, initially only a portion of the test patterns are written to the test register 225. This is the case because the shift registers 202 and 203 in the example under consideration are each designed to store two bits, that is to say to store a total of 4 bits, but the test register 225 can store only two bits. To be more precise, the semiconductor chip's input connection TDI is used first of all to input the least significant bit of the test pattern intended for the shift register 203, and immediately thereafter to input the least significant bit of the test pattern intended for the shift register 202. Subsequently, the register 225-2 in the test register 225 stores the least significant bit of the test pattern intended for the shift register 203, and the register 225-1 in the test register 225 stores the least significant bit of the test pattern intended for the shift register 202.

Next, the bits stored in the test register 225 are transferred into the shift registers 202 and 203. To this end, the state machine 221 is put into the state update_dr by inputting an appropriate bit sequence via the input connection TMS. The result of this is that the clock signal scan_clock is output from the TAP 220, and the bit stored in the register 225-1 is supplied via the multiplexer 278 to the shift register 202 and is stored therein, and at the same time the bit stored in the register 225-2 is supplied via the multiplexer 278 to the shift register 273 and is stored therein.

After that, the state machine 221 is put back into the state shift_dr by inputting an appropriate bit sequence via the semiconductor chip's input connection TMS, and the most significant bits of the test patterns are written to the test register via the semiconductor chip's input connection TDI. To be more precise, after the state machine 221 has been put into the state shift_dr, the semiconductor chip's input connection TDI is used first of all to input the most significant bit of the test pattern intended for the shift register 203, and immediately thereafter to input the most significant bit of the test pattern intended for the shift register 202. After that, the register 225-2 in the test register 225 stores the most significant bit of the test pattern intended for the shift register 203, and the register 225-1 in the test register 225 stores the most significant bit of the test pattern intended for the shift register 202.

Next, the bits stored in the test register 225 are transferred into the shift registers 202 and 203. To this end, the state machine 221 is put back into the state update_dr by inputting an appropriate bit sequence via the input connection TMS. The result of this is that the clock signal scan_clock is output from the TAP 220, and the bit stored in the register 225-1 is supplied via the multiplexer 278 to the shift register 202 and is stored therein while simultaneously performing a shift operation, and at the same time the bit stored in the register 225-2 is supplied via the multiplexer 278 to the shift register 203 and is stored therein while simultaneously performing a shift operation.

Hence, the shift register 202 now stores the most significant and the least significant bit of the test pattern intended for the shift register 202, and the shift register 203 stores the most significant and the least significant bit of the test pattern intended for the shift register 203.

If the shift registers 202 and 203 were to comprise more than two bits, it would also be possible to write the further bits to the shift registers 202 and 203 by repeating the operations described above as explained.

It ought to be clear and requires no further explanation that the shift registers 202 and 203 can also have the test patterns intended for them written to them in the manner described above when the shift registers 202 and 203 are of different length.

When the test patterns to be used have been written to the shift registers 202 and 203, the semiconductor chip is briefly put into a serial scan test/capture mode. In the example under consideration, this is done by virtue of the state machine 221 of the TAP 220 being put into the state capture_dr by inputting appropriate data via the semiconductor chip's input connection TMS. The result of this is that the signal scan_en becomes inactive, and this in turn results in the shift registers 202 and 203 being cleared. Next, the state machine 221 is put into the state update_dr by inputting appropriate data via the semiconductor chip's input connection TMS, as a result of which the TAP 220 outputs the clock signal scan_clock again. In this state of the semiconductor chip, the logic unit in the semiconductor chip, including the flipflops, operates as in the normal mode. Only the clock signal (scan_clock) used is different than in the normal mode (sys_clock). The semiconductor chip is kept in this state only briefly, for example for one or more clock cycles of the clock signal scan_clock. During this time, the data stored by the flipflops may change. Whether and, if appropriate, how they change is dependent, inter alia, on the data which were loaded into the shift registers 202 and 203 beforehand and on the design and operation of the logic unit.

Next, the semiconductor chip is put back into a state in which it is in the serial scan test/shift mode, and the clock signal scan_clock is output from the TAP 220. This is done by virtue of the state machine 221 being put first of all into the state shift_dr and then into the state update_dr. In this state, the data stored in the shift registers 202 and 203 are transferred into the test register 225 and from there are output from the semiconductor chip via the latter's output connection TDO.

Since the shift registers 202 and 203 together are longer than the test register 225, this is done in a plurality of steps in a similar manner to when writing to the shift registers. To be more precise, first of all only the respectively least significant bit of the data stored in the shift registers 202 and 203 is shifted out of the shift registers and transferred into the test register 225. After this transfer, the register 225-1 contains the least significant bit of the data stored in the shift register 202, and the register 225-1 contains the least significant bit of the data stored in the shift register 203.

After that, the state machine 221 is put into the state shift_dr, as a result of which the bits previously transferred into the test register 225 are shifted out of the test register and are output via the semiconductor chip's output connection TDO. At the same time, new test data can be shifted in.

Next, the state machine 221 is put back into the state update_dr, as a result of which the respective most significant bit of the data stored in the shift registers 202 and 203 is transferred into the test register 225. After this transfer, the register 225-1 contains the most significant bit of the data stored in the shift register 202, and the register 225-1 contains the most significant bit of the data stored in the shift register 203.

After that, the state machine 221 is put back into the state shift_dr, as a result of which the bits which have just been transferred into the test register 225 are shifted out of the test register and are output via the semiconductor chip's output connection TDO.

The data which are output from the semiconductor chip via the output connection TDO are then compared with the prescribed nominal data. The nominal data are those data which ought to be stored in the shift registers 202 and/or 203 if the semiconductor chip is operating correctly. The result of the comparison between the data which are output from the shift registers 202 and/or 203 and the nominal data can thus be used to ascertain whether the semiconductor chip is operating correctly. If the data compared with one another match, then it may be assumed that the semiconductor chip has operated correctly. If the data do not match, the semiconductor chip has not operated correctly.

The test described above can be repeated as often as desired using other test patterns.

For the sake of completeness, it should be noted that the control bits which are used to generate the control signals scan_en, scan_mode and jtag_mode do not have to be stored in the instruction register of the TAP. These bits may also be stored in a design specific register as mentioned in IEEE 1149.1. This applies to all of the TAPs presented here.

It should also be noted that the flipflops in the logic unit can be connected up to form any number of shift registers, with the plurality of shift registers being able to be of any length independently of one another.

In addition, the clock signals sys_clock and scan_clock may also be identical clock signals in the case of semiconductor chips of simple design, or the semiconductor chip is always clocked with the clock signal sys_clock.

The semiconductor chips presented here can be comprehensively tested quickly and easily even when they are already integrated in an existing system. Preferably, they can additionally also be tested using the full scan test method, but there is no absolute necessity for this option to be provided.

1. A semiconductor chip comprising a multiplicity of flipflops which can be connected up to form one or more shift registers for the purpose of testing the semiconductor chip, and having a Joint Test Action Group (JTAG) test access port based on IEEE 1149.1 which can be used to put the semiconductor chip into a test mode in which the flipflops are connected up to form one or more shift registers,
wherein
the semiconductor chip is designed such that the one or more shift registers can have information written to and read from it/them via the JTAG test access port.

2. A semiconductor chip according to claim 1,
wherein
the at least one shift register can also have information written to and read from it via input and/or output connections of the semiconductor chip which are not connected to the JTAG test access port.

3. A semiconductor chip according to claim 2,
wherein
the JTAG test access port produces a first signal, whose level governs whether the at least one shift register can have information written to and read from it via the JTAG test access port or via input and/or output connections of the semiconductor chip which are not connected to the JTAG test access port.

4. A semiconductor chip according to claim 3,
wherein
the first signal used is a particular bit of the data stored in an instruction register in the JTAG test access port or is a particular bit of the data stored in one of the other design specific registers defined in IEEE 1149.1.

5. A semiconductor chip according to claim 1,
wherein
the JTAG test access port produces a second signal, whose level governs whether or not the semiconductor chip is in the test mode, and
the second signal is the result of logically combining bits stored in an instruction register in the JTAG test access port or bits stored in one of the other design specific registers defined in IEEE 1149.1.

6. A semiconductor chip according to claim 1,
wherein
the JTAG test access port produces a third signal, whose level governs whether or not the flipflops of the semiconductor chip are connected up to form the at least one shift register, and
the third signal is dependent on the state of a state machine in the JTAG test access port.

7. A semiconductor chip according to claim 1,
wherein
the flipflops of the semiconductor chip are connected up in the test mode at least to form a first shift register and to form a second shift register, and optionally only the first shift register or only the second shift register or both shift registers can have information written to and read from it/them.

8. A semiconductor chip according to claim 7,
wherein
the content of a design specific register in the JTAG test access port, which register is defined in IEEE 1149.1 and can have information written to it via an input connection TDI of the JTAG test access port, governs whether only the first shift register or only the second shift register or both shift registers can have information written to and read from it/them.

9. A semiconductor chip according to claim 1,
wherein
the data to be written to the at least one shift register are input into the semiconductor chip via an input connection TDI of the JTAG test access port.

10. A semiconductor chip according to claim 9,
wherein
the data to be written to the at least one shift register are written to a design specific register which is defined in IEEE 1149.1 and can have information written to it via the input connection TDI of the JTAG test access port, and are forwarded from there to the at least one shift register.

11. A semiconductor chip according to claim 10,
wherein
the data to be written to the at least one shift register are written to the design specific register serially bit by bit and are forwarded therefrom to the at least one shift register in parallel.

12. A semiconductor chip according to claim 10,
wherein
the at least one shift register has information written to it in a plurality of successive steps, with one bit per shift register being written to the design specific register and being forwarded from there to the at least one shift register in each step.

13. A semiconductor chip according to claim 1,
wherein
the data to be read from the at least one shift register are output from the semiconductor chip via an output connection TDO of the JTAG test access port.

14. A semiconductor chip according to claim 13,
wherein
the data to be read from the at least one shift register are transferred to a design specific register in the JTAG test access port, which register is defined in IEEE 1149.1, and from there are output from the semiconductor chip via the output connection TDO of the JTAG test access port.

15. A semiconductor chip according to claim 14,
wherein
the data to be read from the at least one shift register are transferred in parallel to the design specific register and from there are output serially bit by bit from the semiconductor chip via the output connection TDO of the JTAG test access port.

16. A semiconductor chip according to claim 14,
wherein
information is read from the at least one shift register in a plurality of successive steps, with one bit per shift register being written in parallel to the design specific register and from there being output serially bit by bit from the semiconductor chip in each step.

17. A semiconductor chip according to claim 1,
wherein
the JTAG test access port is supplied with a clock signal via an input connection TCK, said clock signal being able to be used to clock the semiconductor chip in the test mode, and the JTAG test access port forwards this clock signal to the remaining components of the semiconductor chip only in particular phases.

18. A semiconductor chip according to claim 17,
wherein
the state of a state machine in the JTAG test access port and/or the content of an instruction register in the JTAG test access port govern(s) whether the JTAG test access port forwards the clock signal to the remaining components of the semiconductor chip.

19. A semiconductor chip comprising a multiplicity of flipflops which are connected up to form one or more shift registers for the purpose of testing the semiconductor chip, and having a Joint Test Action Group (JTAG) test access port based on IEEE 1149.1 which can be used to put the semiconductor chip into a test mode in which the flipflops are connected up to form one or more shift registers,
wherein
the one or more shift registers are read- and writeable via the JTAG test access port.

20. A semiconductor chip according to claim 19,
wherein
the at least one shift register can also have information written to and read from it via input and/or output connections of the semiconductor chip which are not connected to the JTAG test access port,
the JTAG test access port produces a first signal, whose level governs whether the at least one shift register can have information written to and read from it via the JTAG test access port or via input and/or output connections of the semiconductor chip which are not connected to the JTAG test access port, and wherein
the first signal used is a particular bit of the data stored in an instruction register in the JTAG test access port or is a particular bit of the data stored in one of the other design specific registers defined in IEEE 1149.1.
